(19) United States
(12) Patent Application Publication
(10) Pub. No.: US 2008/0309204 A1
(43) Pub. Date: Dec. 18, 2008

(54) CIRCUIT BOARD AND BRUSHLESS MOTOR USING THE SAME

(75) Inventor: Masahiro Yamada, Minami-ku (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: NIDEC CORPORATION, Minami-ku (JP)

(21) Appl. No.: 12/139,681

(22) Filed: Jun. 16, 2008

(30) Foreign Application Priority Data
Jun. 14, 2007 (JP) 2007-157983

(51) Int. Cl. H02K 11/00; H05K 1/02

(52) U.S. Cl. 310/68 B; 174/261

(57) ABSTRACT

A circuit board is used for allowing an electric current to conduct to a position detection unit and a stator having a winding for generating rotating magnetic fields for a brushless motor. The circuit board includes a winding connection portion that connects ends of the winding to the circuit board; and a first terminal portion electrically connected to the position detection unit installed outside of a circumferential surface of the circuit board.

### FIELD OF THE INVENTION

The present invention relates to a disk drive apparatus for recording and reproducing an optical recording disk; and, more particularly, to a circuit board of a brushless motor for rotating the recording disk.

### BACKGROUND OF THE INVENTION

Conventionally, there is known a disk drive apparatus having a function of burning various pictures and writing characters on a surface of a recording disk to be recorded or reproduced (hereinafter simply referred to as a labeling function). A sensor for exclusive use in low-speed rotation is needed to perform the labeling function because the recording disk is rotated by a brushless motor at a very low speed, e.g., at a speed of several tens revolutions per minute, during execution of the labeling function. Use of this sensor ensures that the recording disk is rotated at a low speed with increased accuracy, thereby making it possible to draw pictures or characters on the surface of the recording disk without causing unevenness to the pictures or characters (see, e.g., Patent Document 1 for an example of the disk drive apparatus having such a labeling function).

(Patent Document 1) Japanese patent Application Publication No. 2006-236535A

At the present time, however, the labeling function is absent in some disk drive apparatuses. It is sometimes the case that the brushless motors for rotating the recording disk in the disk drive apparatuses are of the same type regardless of the presence or absence of the labeling function. In this case, depending on the kinds of the disk drive apparatuses, there exists a need to prepare two kinds of circuit boards for the brushless motors, i.e., a circuit board with the labeling function and that without the labeling function. This is because sensors for exclusive use in low-speed rotation are mounted to the circuit boards of the brushless motors. As a consequence, there is a possibility that the price of the brushless motors grows higher.

### SUMMARY OF THE INVENTION

In view of the above, the present invention provides a commonly usable circuit board that can be used regardless of the presence or absence of a labeling function; and a brushless motor equipped with the circuit board.

In accordance with a first aspect of the present invention, there is provided a circuit board for allowing an electric current to conduct to a position detection unit and a stator having a winding for generating rotating magnetic fields for a brushless motor, the circuit board including a winding connection portion that connects ends of the winding to the circuit board; and a first terminal portion electrically connected to the position detection unit installed outside of a circumferential surface of the circuit board.

In this configuration, since the position detection unit is not mounted on the circuit board, it is possible to prevent the position detection unit from being affected by thermal shrinkage under a high temperature environment. This makes it possible to prevent the position detection unit from being influenced by an external environment, thereby increasing the accuracy with which the position detection unit is arranged.

Further, there is provided a motor driving unit including the circuit board of the above and the position detection unit, wherein the position detection unit includes a position detecting element, a supporting base having an upper surface on which the position detecting element is arranged, and a second terminal portion for electrically connecting the position detecting element to the first terminal portion.

In this configuration, use of the supporting base provides a degree of freedom in setting the vertical position of the position detecting element. Therefore, it is possible for the position detecting element to detect the position of an object at an optimized vertical position.

Further, it is preferable that the position detection unit further includes a flexible circuit strip extending between the upper surface of the supporting base and the position detecting element, and the second terminal portion is provided in the circuit strip.

In this configuration, since the circuit strip is flexible and is provided with the second terminal portion, it is easy to electrically connect the first terminal portion of the circuit board to the second terminal portion of the circuit strip even if the circuit board and the supporting base differ in thickness from each other.

Further, it is preferable that the circuit strip is fixed to an upper surface of the circuit board at a region between the position detecting element and the second terminal portion.

In this configuration, since the region of the circuit strip near the second terminal portion is partly fixed to the circuit board, it is possible to arrange the second terminal portion relative to the first terminal portion in a stable state. In other words, it is possible to prevent the second terminal portion from being misaligned with the first terminal portion. Furthermore, since the circuit board and the circuit strip are fixed to each other in between the first terminal portion and the position detecting element, it is possible to prevent a force from being directly imparted on the second terminal portion even when the circuit strip is pulled away from the circuit board due to, e.g., an external impact. This makes it possible to restrain the first terminal portion and the second terminal portion from suffering from bad conduction.

Further, it is preferable that the first terminal portion and the second terminal portion are soldered together.

In this configuration, since the first terminal portion and the second terminal portion are soldered together, it is easy to electrically connect the first terminal portion and the second terminal portion.

Further, it is preferable that a uniformly planar attachment plate formed of a thin plate is fixed to a lower surface of the circuit board, the position detection unit is attached to an upper surface of the attachment plate, and the positions of the circuit board and the position detection unit are decided by a circuit board positioning portion and a position detection unit positioning portion provided in the attachment plate.

In this configuration, since the position detection unit is attached to the upper surface of the attachment plate but not attached to the upper surface of the circuit board, it is possible to assure positional accuracy of the position detection unit with respect to a specified center axis without being affected by thermal expansion of the circuit board. This makes it possible to provide a circuit board capable of maintaining its position detection accuracy without being affected by an external environment.

In accordance with a second aspect of the present invention, there is provided a brushless motor including the motor driving unit of the above; a fixed unit having a stator; and a rotating unit rotatable about a specified center axis, having a rotor magnet arranged in a facing relationship with the stator. Herein, the position detection unit is arranged radially outwardly of the rotating unit.

With this configuration, it is possible to provide a brushless motor that exhibits increased position detection accuracy.

In accordance with a third aspect of the present invention, there is provided a circuit board unit including a uniformly planar attachment plate formed of a thin plate; and a substantially flat circuit board arranged on an upper surface of the attachment plate. Herein, the circuit board allows an electric current to conduct to a position detection unit and a stator having a winding for generating rotating magnetic fields for a brushless motor. Further, the position detection unit is attached to the upper surface of the attachment plate, and positions of the circuit board and the position detection unit are decided by a circuit board positioning portion and at least one position detection unit positioning portion provided in the attachment plate.

In this configuration, since the positions of the circuit board and the position detection unit are individually decided by the attachment plate, it is possible to prevent the positions of the circuit board and the position detection unit from being affected by cumulative dimensional errors. In a hypothetical case that the position detection unit is mounted on the circuit board, the dimensional error of the circuit board needs to be taken into account. For this reason, the positional accuracy of the position detection unit is affected by the dimensional error of the attachment plate plus the dimensional error of the circuit board, which makes it difficult to accurately position the position detection unit. In the present invention, however, the positions of the circuit board and the position detection unit are decided by the attachment plate. This makes it possible to position the position detection unit within the extent of the dimensional error of the attachment plate without having to take the dimensional error of the circuit board into account.

It is preferable that the attachment plate is formed by press-forming a thin plate, and each of the circuit board positioning portion and the position detection unit positioning portion is a through-hole and is formed simultaneously with the press-forming.

In this configuration, since the attachment plate is formed by press-forming a thin plate, it is possible to cost-effectively produce the attachment plate. Furthermore, since each of the circuit board positioning portion and the position detection unit positioning portion is formed as a through-hole, it can be formed by using a single surface of a press mold. This makes it possible to restrain the positional errors of the circuit board positioning portion and the position detection unit positioning portion within the extent of the dimensional errors of one surface of the press mold. Therefore, it is possible to arrange the circuit board and the position detection unit with increased accuracy.

Further, it is preferable that the position detection unit includes a position detecting element; and a supporting base having an upper surface on which the position detecting element is arranged, wherein the supporting base is provided with a protrusion portion inserted into the position detection unit positioning portion, and the position detection unit positioning portion is provided in plural numbers, at least one of which is a slot extending toward a rotational center of the brushless motor.

With this configuration, it is possible to adjust the position of the position detection unit, thereby further increasing the positional accuracy of the position detection unit.

In accordance with a fourth aspect of the present invention, there is provided a brushless motor including the circuit board unit of the above; a fixed unit having a stator; and a rotating unit rotatable about a specified center axis, having a rotor magnet arranged in a facing relationship with the stator. Herein, the position detection unit is arranged radially outwardly of the rotating unit.

With this configuration, it is possible to provide a brushless motor that enjoys increased position detection accuracy.

In accordance with the present invention, it is possible to provide a commonly usable circuit board that can be used regardless of the presence or absence of a labeling function; and a brushless motor equipped with the circuit board.

### BRIEF DESCRIPTION OF THE DRAWINGS

FIG. 1 is an axially-cut schematic section view showing a brushless motor in accordance with one embodiment of the present invention.

FIG. 2 is a top plan view showing the brushless motor in accordance with one embodiment of the present invention.

FIG. 3 is a side view showing the brushless motor in accordance with one embodiment of the present invention.

FIG. 4 is a top plan view illustrating a position detection unit of the present invention.

FIG. 5 is a schematic view depicting the relationship between the position detection unit of the present invention and a recording disk.

FIG. 6A is a top plan view illustrating a circuit board of the present invention and FIG. 6B is a bottom plan view thereof.

FIG. 7 is a top plan view illustrating a flexible circuit strip of the present invention.

FIG. 8A is a top plan view illustrating a reinforcing plate of the present invention and FIG. 8B is a right side view thereof.

FIG. 9A is a top plan view illustrating a supporting base of the present invention, FIG. 9B is a bottom plan view thereof and FIG. 9C is a side view thereof.

FIG. 10 is a schematic exploded perspective view showing how to assemble the position detection unit of the present invention.

FIG. 11 is a top plan view showing an attachment plate of the present invention.

FIG. 12 a schematic exploded perspective view showing how to assemble the attachment plate and a circuit board.

FIG. 13 a schematic exploded perspective view showing how to assemble the attachment plate and the position detection unit.

FIG. 14 a schematic perspective view showing the circuit board and the position detection unit attached to the attachment plate of the present invention.

FIG. 15 a schematic perspective view illustrating a state that the circuit board and the position detection unit shown in FIG. 14 have been subjected to soldering.

### DETAILED DESCRIPTION OF THE PREFERRED EMBODIMENTS

### Structure of a Brushless Motor

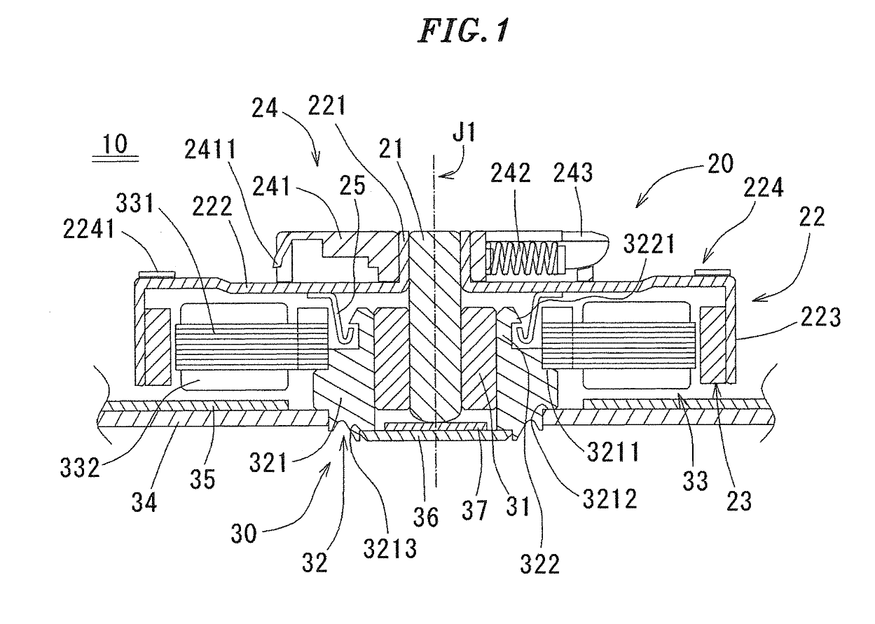

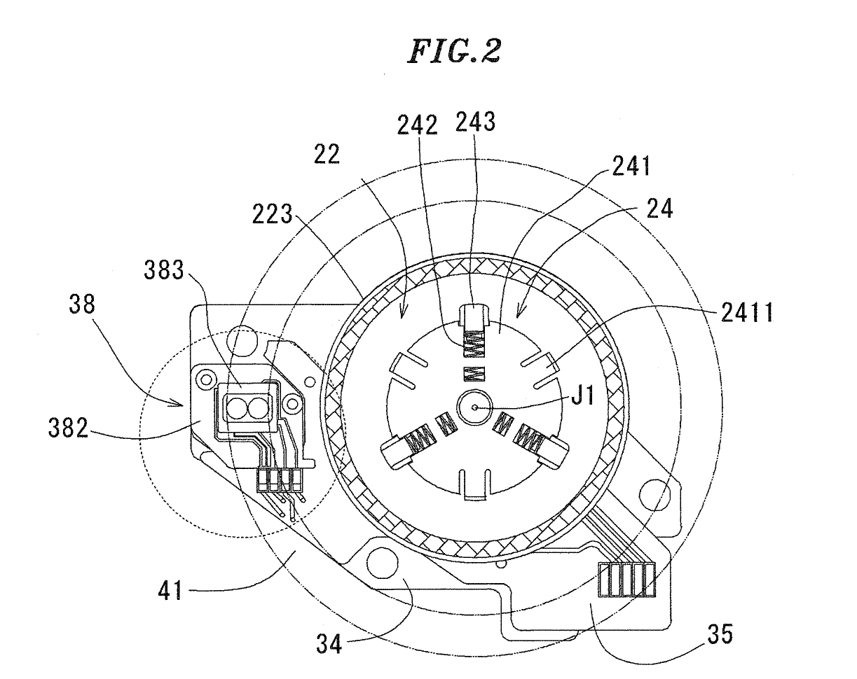

One embodiment of a brushless motor in accordance with the present invention will now be described with reference to FIGS. 1 and 2. FIG. 1 is an axially-cut schematic section view showing a brushless motor in accordance with one embodiment of the present invention. FIG. 2 is a top plan view showing the brushless motor.

Referring to FIG. 1, a brushless motor 10 of the present invention includes a rotating unit 20 designed to rotate about a specified center axis J1 to thereby turn a recording disk (not shown in FIG. 1); the rotating unit 20 provided with a below-mentioned rotor magnet 23; and a fixed unit 30 provided with a below-mentioned stator 33 having a surface radially facing the rotor magnet 23.

First, description will be made regarding the rotating unit 20.

The rotating unit 20 includes a shaft 21 arranged in a coaxial relationship with the center axis J1; a rotor holder 22 fixed to the shaft 21; a rotor magnet 23 fixedly secured to the rotor holder 22; and a chucking device 24 arranged above the rotor holder 22.

The rotor holder 22 includes a generally cylindrical shaft-fixed portion 221 fixed to an outer circumferential surface of the shaft 21, a planar cover portion 222 extending radially outwardly from an axial lower end of the shaft-fixed portion 221 and a cylinder portion 223 extending axially downwardly from an outer circumferential edge of the cover portion 222. The rotor magnet 23 is of a generally cylindrical shape and is fixed to an inner circumferential surface of the cylinder portion 223.

A disk support portion 224 axially upwardly protruding from the cover portion 222 and remaining in a generally parallel relationship with the cover portion 222 is formed radially outwardly of the cover portion 222 of the rotor holder 22. A disk support member 2241 formed of an annular rubber piece is provided in a radially outward region of the disk support portion 224.

The chucking device 24 is fixed to an outer circumferential surface of the shaft-fixed portion 221 of the rotor holder 22. The chucking device 24 includes a center case 241 making contact with a central opening portion of a recording disk (not shown); a coil spring 242 (three coil springs in the present embodiment as shown in FIG. 2) received in the center case 241; and a chucking claw 243 (three chucking claws in the present embodiment as shown in FIG. 2) radially outwardly biased by means of the coil spring 242. The chucking claw 243 holds the recording disk in place by making contact with an upper edge of the central opening portion of the recording disk. An aligning claw 2411 (three chucking claws in the present embodiment as shown in FIG. 2) is integrally formed with the center case 241. The aligning claw 2411 makes contact with the central opening portion of the recording disk, thereby bringing the center of the central opening portion into alignment with the center axis J1.

Next, description will be made regarding the fixed unit 30.

The fixed unit 30 includes a generally cylindrical sleeve 31 having an inner circumferential surface for rotatably supporting the shaft 21 in a radial direction; a housing 32 having an inner circumferential surface for holding an outer circumferential surface of the sleeve 31; a stator 33 fixed to the housing 32; an attachment plate 34 arranged axially below the stator 33; a substantially flat circuit board 35 fixed to an upper surface of the attachment plate 34; a disk-like plate 36 for covering an axial lower end of an inner circumferential surface of the housing 32; and a thrust plate 37 arranged on an upper surface of the plate 36.

The housing 32 is formed of a base portion 321 for fixing the stator 33 and a cylinder portion 322 extending axially upwardly from the base portion 321. The inner circumferential surface of the housing 32 is formed of an inner circumferential surface of the base portion 321 and an inner circumferential surface of the cylinder portion 322.

The stator 33 is fixed to a first outer circumferential end portion 3211 formed on the upper side of the base portion 321. The attachment plate 34 is fixed to a second outer circumferential end portion 3212 formed on the lower side of the base portion 321. The plate 36 is fixed to an inner circumferential end portion 3213 formed on the lower side of the base portion 321.

On the axial upper side of the cylinder portion 322 of the housing 32, a radially outwardly protruding locking portion 3221 is integrally formed with the cylinder portion 322. The locking portion 3221 has an outer circumferential surface formed of an axially downwardly and radially outwardly slanting surface. A removal-proof member 25 is fixed to a lower surface of the cover portion 222 of the rotor holder 22. The locking portion 3221 and the removal-proof member 25 cooperate to restrain the rotating unit 20 from moving axially upwardly.

The stator 33 includes a stator core 331 formed of a plurality of axially layered thin magnetic plates; and a plurality of coils 332 formed of a conductive wire wound around the stator core 331. The stator core 331 has an outer circumferential surface radially facing an inner circumferential surface of the rotor magnet 23. The plurality of coils 332 is generally referred to as a winding.

The stator 33 generates magnetic fields as an electric current is supplied to the coils 332 of the stator 33. The rotor magnet 23 and the stator 33 cooperate to form rotating magnetic fields, thereby generating a torque about the center axis J1 to rotate the rotating unit 20.

A position detection unit 38 for reading the information of a below-mentioned pattern formation portion (not shown) of a label surface (i.e., a rear surface) of the recording disk (not shown) is attached to the attachment plate 34 in a radially outward position from the rotating unit 20. When characters or pictures are drawn on the label surface of the disk, the rotating unit 20 is controlled to rotate at a low speed by use of the information issued from the position detection unit 38. Herein, the position detection unit 38 corresponds to the sensor for exclusive use in low-speed rotation, which was discussed above. Further, the circuit board 35 and the position detection unit 38 serve as a motor driving unit.

(Position Detection Unit and Surrounding Structure)

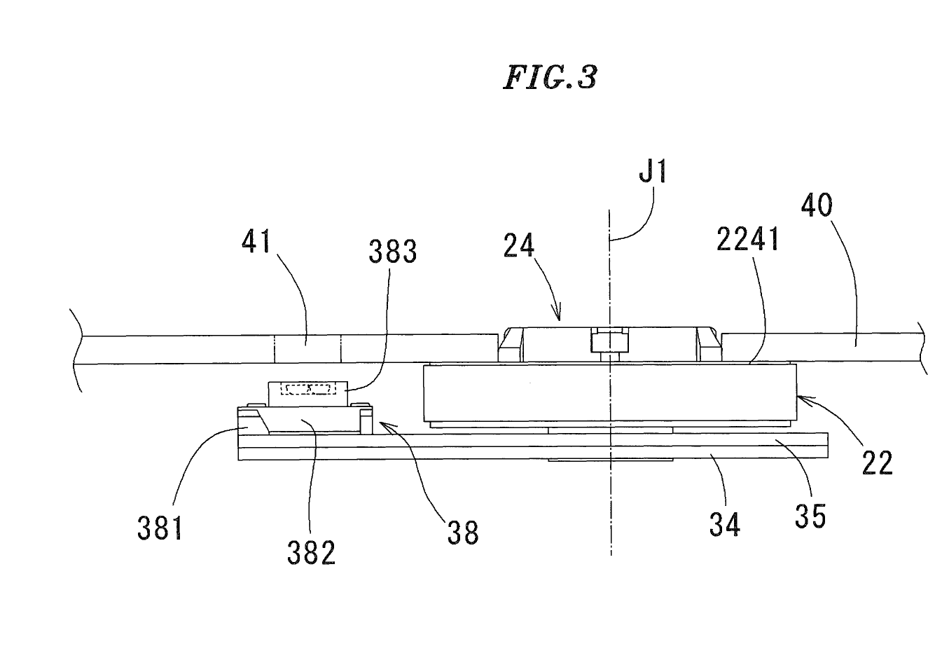

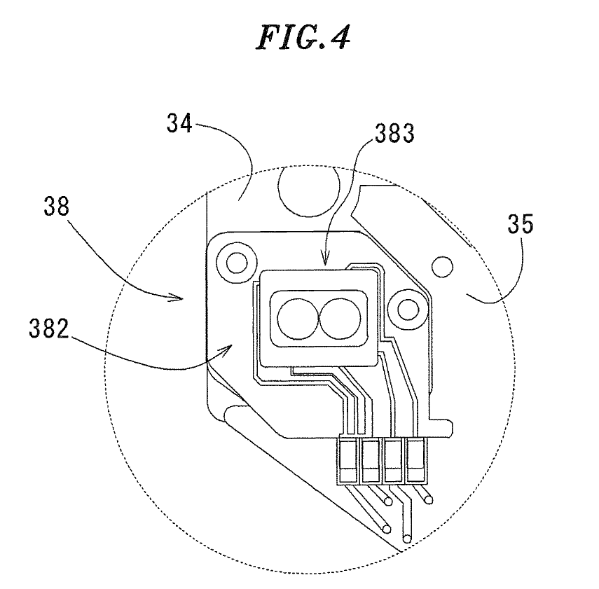

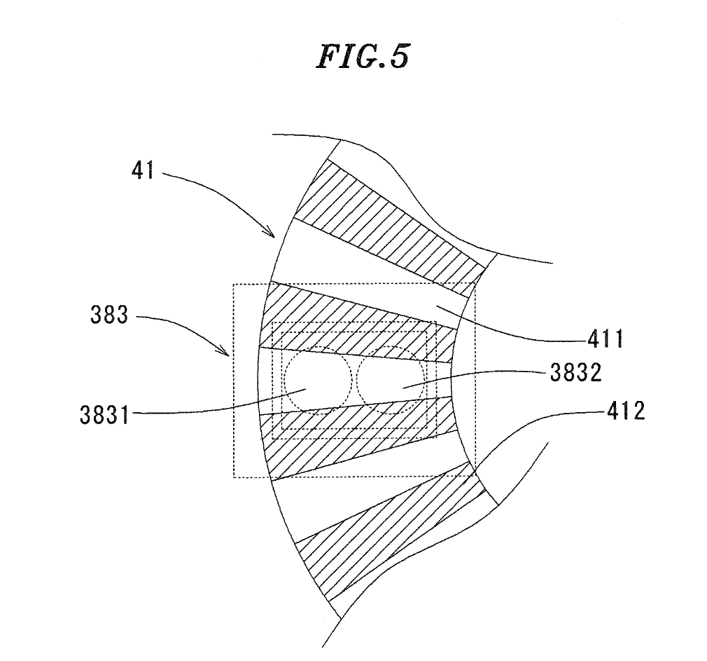

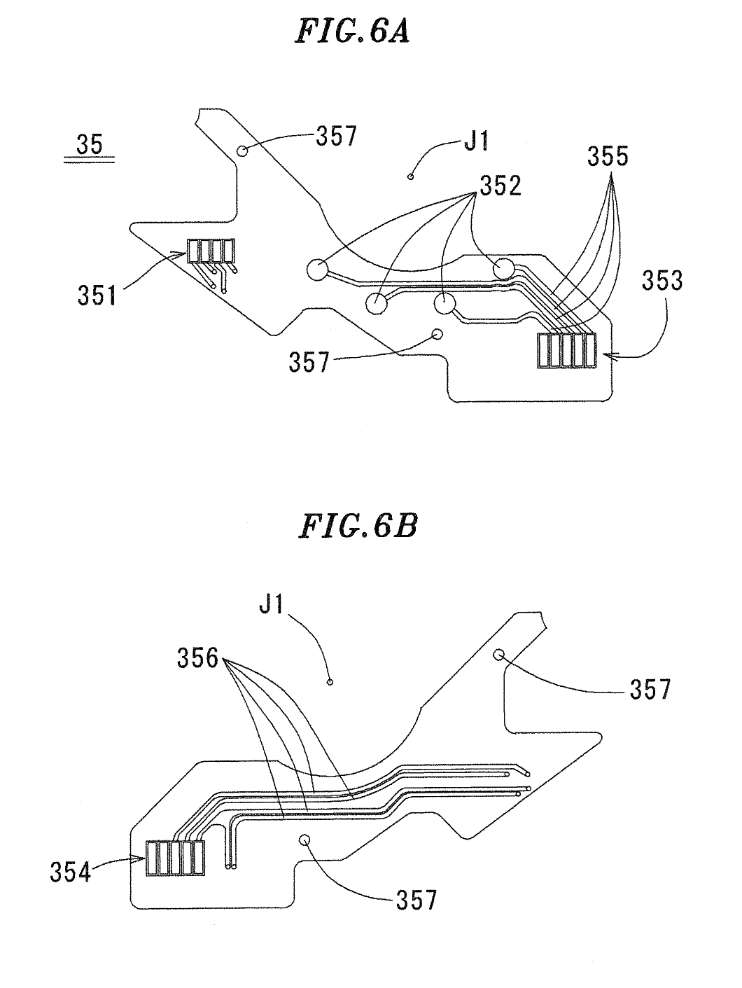

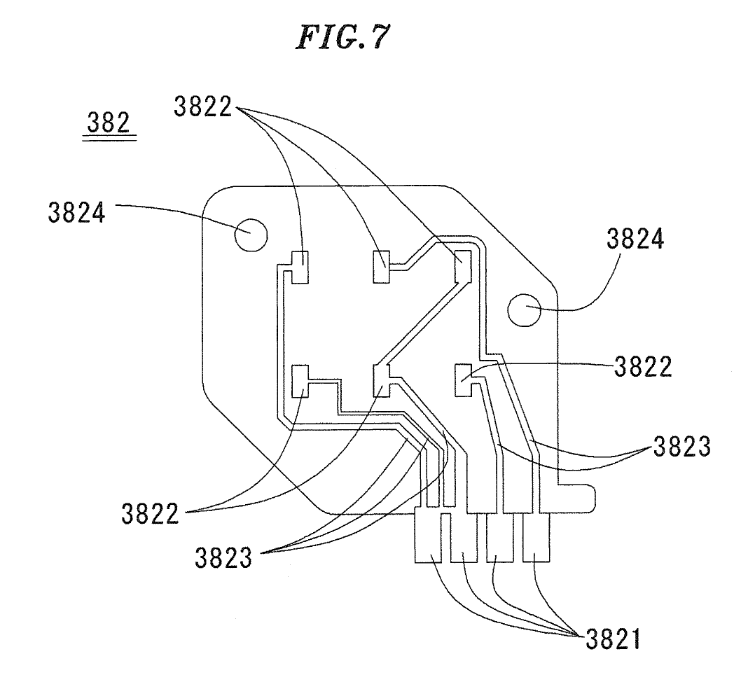

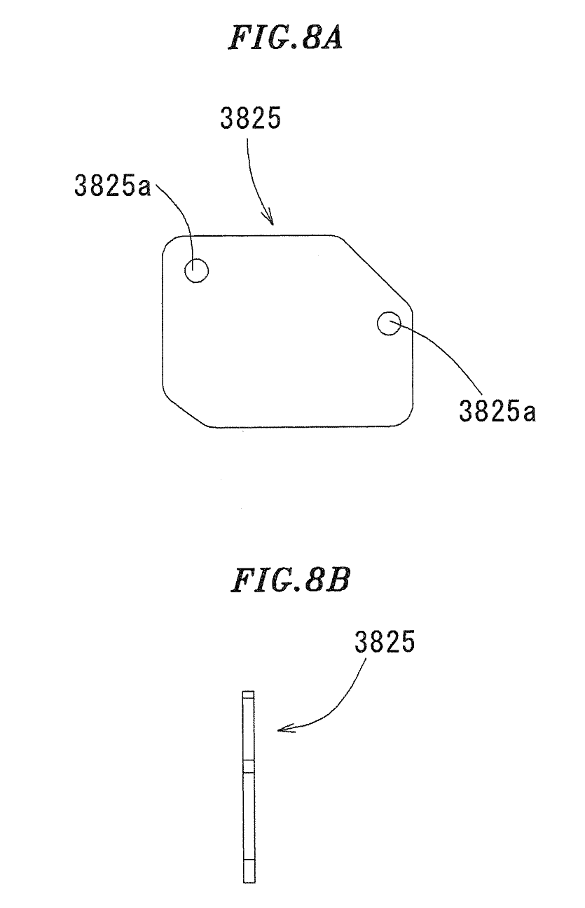

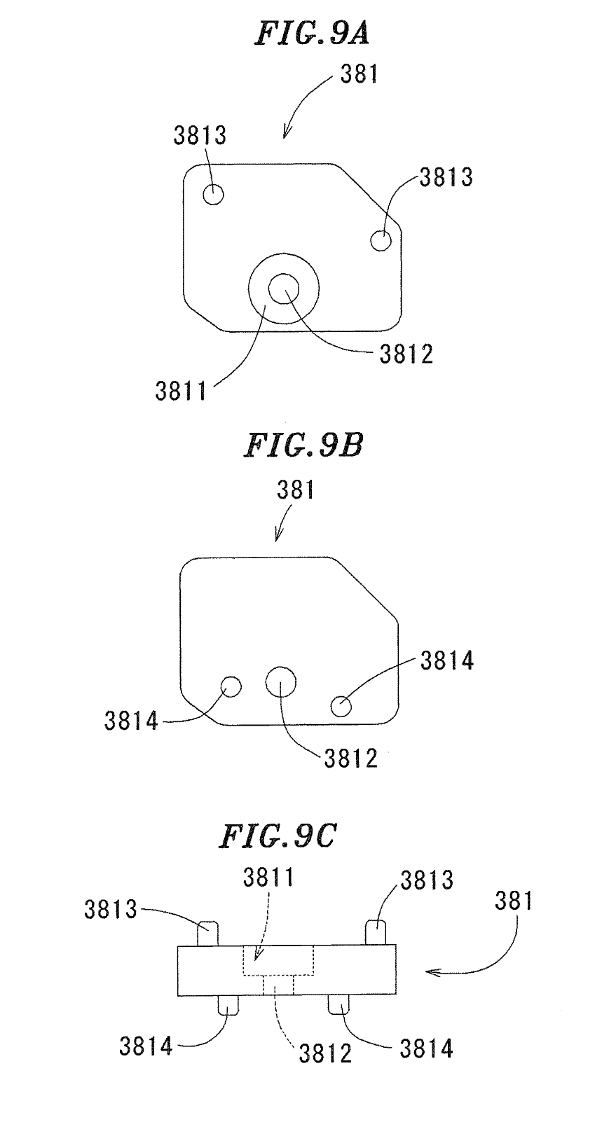

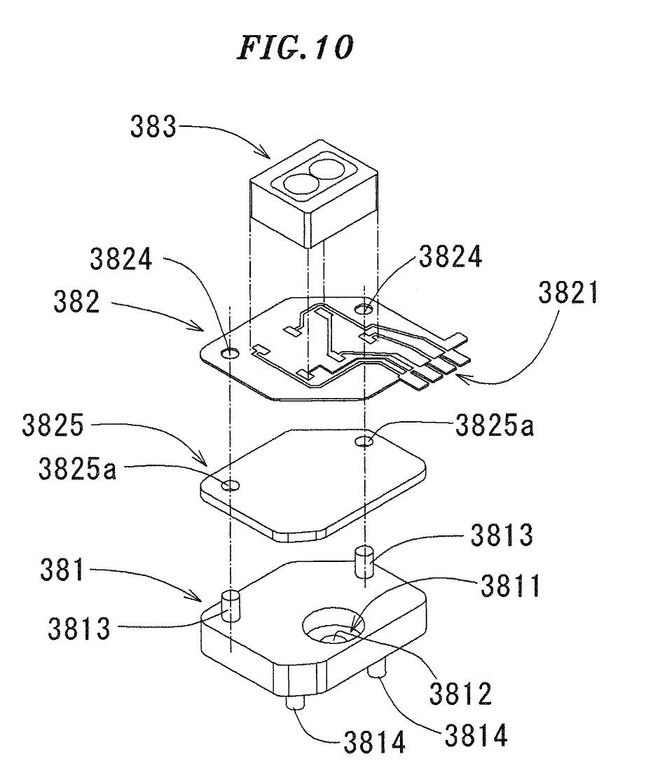

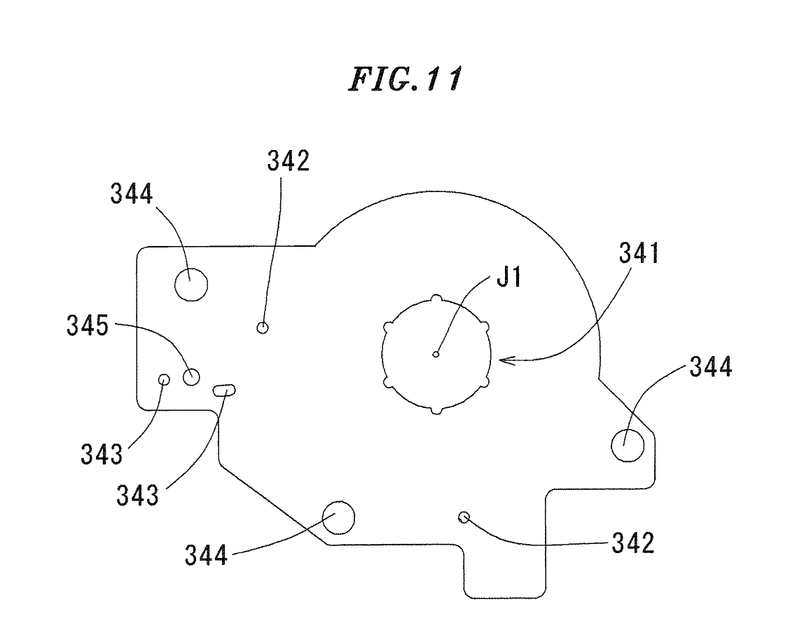

Next, the position detection unit and its surrounding structure will be described with reference to FIGS. 2 to 11. FIG. 3 is a side view showing the brushless motor in accordance with one embodiment of the present invention. FIG. 4 is a top plan view illustrating the position detection unit of the present invention. FIG. 5 is a schematic view depicting the relationship between the position detection unit and the recording disk. FIG. 6A is a top plan view illustrating the circuit board 35 and FIG. 6B is a bottom plan view thereof. FIG. 7 is a top plan view illustrating a flexible circuit strip 382. FIG. 8A is a top plan view illustrating a reinforcing plate 3825 and FIG. 8B is a right side view thereof. FIG. 9A is a top plan view illustrating a supporting base 381, FIG. 9B is a bottom plan view thereof and FIG. 9C is a side view thereof. FIG. 10 is a schematic exploded perspective view showing the position detection unit 38. Screws are not shown in FIG. 10. FIG. 11 is a top plan view showing the attachment plate 34.

Referring to FIGS. 2 to 4, the position detection unit 38 is arranged radially outwardly of the cylinder portion 223 of the rotor holder 22. The position detection unit 38 includes a supporting base 381 fixed to the attachment plate 34; a flexible circuit strip 382 fixed to an upper surface of the supporting base 381; and a position detecting element 383 mounted to an upper surface of the flexible circuit strip 382. Herein, the flexible circuit strip 382 is electrically connected to the circuit board 35. The supporting base 381 is made of, e.g., resin, and is fastened to the attachment plate 34 by means of screws.

Referring to FIGS. 2 and 3, an annular pattern formation portion 41 (the region between double-dotted chain lines in FIG. 2) is formed in the disk 40. The pattern formation portion 41 is formed substantially in the same position as the radial position of the position detecting element 383. That is to say, the position detecting element 383 and the pattern formation portion 41 lie in an axially facing relationship with each other. In this connection, it is preferred that a photo sensor for emitting and receiving light be used as the position detecting element 383. The position detecting element 383 has a detection surface positioned on the upper surface thereof. The position detecting element 383 is arranged axially a bit below the disk support member 2241. When the disk 40 is placed on an axial upper surface of the disk support member 2241, the detection surface of the position detecting element 383 faces an axial lower surface of the disk 40 with a small gap (of about 2 mm) left therebetween.

Referring to FIG. 5, the pattern formation portion 41 of the disk 40 is formed of a reflective pattern portion 411 and a non-reflective pattern portion 412 alternately arranged in a circumferential direction, each of the pattern portions 411 and 412 having a specified width. The position detecting element 383 includes a light-emitting portion 3831 for emitting light and a light-receiving portion 3832 for receiving light. The light emitted from the light-emitting portion 3831 is reflected by the reflective pattern portion 411 and then received by the light-receiving portion 3832. On the other hand, the non-reflective pattern portion 412 absorbs the light emitted from the light-emitting portion 3831, whereby the light is not received by the light-receiving portion 3832. This makes it possible to obtain pulse signals according to the bright and dark pattern of the pattern formation portion 41. The disk 40 has a recording surface formed on one axial side thereof. The pattern formation portion 41 is formed on the label surface, i.e., the axially opposite surface of the disk 40 from the recording surface.

The brushless motor having the position detection unit 38 is arranged within the disk drive apparatus. A laser pickup device (not shown) movable in a radial direction of the disk 40 for gaining access to the recording surface of the disk 40 is provided within the disk drive apparatus on the side of the attachment plate 34 with respect to the disk 40 placed on the disk support member 2241 of the rotor holder 22 of the rotating unit 20.

Once the disk 40 is placed on the rotor holder 22 and the disk support member 2241 in a state that the label surface faces the attachment plate 34, the position detecting element 383 optically detects the position of the pattern formation portion 41 formed on the label surface. Responsive to the position detection signals thus generated, the rotating unit 20 is controlled to rotate at a low speed. Then, the laser pickup device draws pictures or letters on the label surface of the disk 40.

Referring to FIG. 6A, the upper surface of the circuit board 35 includes a first terminal portion 351 electrically connected to the flexible circuit strip 382; a winding connection portion 352 electrically connected to the ends of the winding; and a first external connection portion 353 electrically connected to an external power source (or an external control circuit). The winding connection portion 352 and the first external connection portion 353 are electrically connected to each other by means of a first wiring pattern 355 formed of a copper foil having a thin film wire shape.

Referring to FIG. 6B, a second external connection portion 354 arranged substantially in the same radial and circumferential position as that of the first external connection portion 353 is provided on the lower surface of the circuit board 35. The first terminal portion 351 and the second external connection portion 354 are electrically connected to each other by means of a second wiring pattern 356 formed of a copper foil having a thin film wire shape. Conductive portions made of a copper foil are formed in the respective connection portions including the first terminal portion 351, the winding connection portion 352, the first external connection portion 353 and the second external connection portion 354. Insulating films for assuring electrical insulation are coated on the upper and lower surfaces of the circuit board 35. No insulating film is coated on the conductive portions of the respective connection portions.

Referring to FIG. 7, the flexible circuit strip 382 includes a second terminal portion 3821 electrically connected to the first terminal portion 351 of the circuit board 35; a position detecting element connection portion 3822 electrically connected to the position detecting element 383; and a third wiring pattern 3823 for electrically connecting the second terminal portion 3821 and the position detecting element connection portion 3822. The third wiring pattern 3823 is made of a copper foil having a thin film wire shape. The flexible circuit strip 382 has two positioning holes 3824 that assist in deciding the position of the flexible circuit strip 382 relative to the supporting base 381. An insulating film for assuring electrical insulation is coated on the upper surface of the flexible circuit strip 382.

The second terminal portion 3821 is formed of a plurality of thin copper plates. The second terminal portion 3821 is not subjected to plating such as gold plating or the like but merely subjected to a heat-resistant flux treatment. No insulating film is coated on the second terminal portion 3821. In case of applying a gold coat on the second terminal portion 3821, a nickel coat is applied on the second terminal portion 3821 as a base layer of the gold coat. This is to ensure that the gold coat is more reliably applied on the second terminal portion 3821.

Since the nickel coat is weak against bending, there is a possibility that the second terminal portion 3821 suffers from disconnection when the second terminal portion 3821 is bent by the contact with other members. This makes it impossible to electrically interconnect the position detecting element 383 and the circuit board 35. Owing to the fact that neither gold coat nor nickel coat is applied on the second terminal portion 3821 in the present embodiment (since the second terminal portion 3821 is made of copper alone), the second terminal portion 3821 becomes stronger against bending than when the nickel coat is applied thereon. This makes it possible to prevent disconnection of the second terminal portion 3821.

A reinforcing plate 3825 formed of a resin material having a thin plate shape is bonded to the lower surface of the flexible circuit strip 382 by means of an adhesive agent. The reinforcing plate 3825 is nearly identical in shape with the outer circumferential edge of the supporting base 381. Plate positioning holes 3825a are formed in the reinforcing plate 3825 in the positions corresponding to the positioning holes 3824 of the flexible circuit strip 382. Use of the reinforcing plate 3825 makes it possible to accurately fix the flexible circuit strip 382 to the upper surface of the supporting base 381.

The flexible circuit strip 382 of the present embodiment is so thin as to have a thickness of about 0.05 mm and is made of a soft material such as a resin material or the like. For this reason, if the flexible circuit strip 382 alone is fixed to the upper surface of the supporting base 381, there is a possibility that the flexible circuit strip 382 is fixed in an axially irregular shape (i.e., in an undulating shape). As a result, the upper surface of the position detecting element 383 fixed to the upper surface of the flexible circuit strip 382 is inclined relative to the center axis J1 (That is to say, the upper surface of the position detecting element 383 comes out of parallelism with the direction perpendicular to the center axis J1). Therefore, there is a fear that the information on the pattern formation portion 41 of the disk 40 cannot be detected with increased accuracy.

In the present embodiment, since the reinforcing plate 3825 is attached to the lower surface of the flexible circuit strip 382 to thereby allow the lower surface of the reinforcing plate 3825 to make contact with the upper surface of the supporting base 381, it is possible to restrain the flexible circuit strip 382 from being deformed into an axially irregular shape. Therefore, there is no possibility that the upper surface of the position detecting element 383 is inclined relative to the center axis J1 (That is to say, the upper surface of the position detecting element 383 is kept in a parallel relationship with the direction perpendicular to the center axis J1). Consequently, it becomes possible to detect the information on the pattern formation portion 41 with increased accuracy.

Referring to FIGS. 9A to 9C and FIG. 10, the supporting base 381 is formed into a generally rectangular solid shape. In the central region of the supporting base 381, there is formed a recess portion 3811 axially downwardly depressed from the upper surface of the supporting base 381. A through-hole 3812 communicating with the lower surface of the supporting base 381 is formed in the center region of the recess portion 3811.

In the marginal region of the upper surface of the supporting base 381 spaced apart from the recess portion 3811, there are formed upper protrusion portions 3813 that protrude axially upwardly. The upper protrusion portions 3813 are provided in two positions with the recess portion 3811 radially interposed therebetween. The upper protrusion portions 3813 are inserted into the positioning hole 3824 of the flexible circuit strip 382 and the plate positioning holes 3825a of the reinforcing plate 3825 (see FIG. 10).

On the lower surface of the supporting base 381 (namely, on the surface of the supporting base 381 making contact with the attachment plate 34), there are formed two cylindrical lower protrusion portions 3814 that protrude axially downwardly. The lower protrusion portions 3814 are inserted into the below-mentioned second positioning holes 343 of the attachment plate 34. This makes it possible to decide the radial and circumferential position of the supporting base 381 relative to the attachment plate 34.

Referring to FIG. 11, the attachment plate 34 is formed by punching a thin steel plate with a press working mold. The attachment plate 34 includes a central through-hole 341 having a center coaxial with the center axis J1; first positioning holes 342 serving as circuit board positioning portions for deciding the radial and circumferential position of the circuit board 35; second positioning holes 343 serving as position detection unit positioning portions fitted to the lower protrusion portions 3814 of the supporting base 381; and a plurality of attachment holes 344 (three attachment holes in the present embodiment) for use in attaching the brushless motor to other members. The first positioning holes 342 and the second positioning holes 343 are formed simultaneously with press working. The first positioning holes 342 and the second positioning holes 343 are two in number, respectively. One of the second positioning holes 343 is a slot elongated in a radial direction. In the position corresponding to the through-hole 3812 of the supporting base 381, there is formed a supporting base fastening hole 345 through which a screw is tightened to fix the supporting base 381 to the attachment plate 34.

(Structure for Attaching the Circuit Board and the Position Detection Unit to the Attachment Plate)

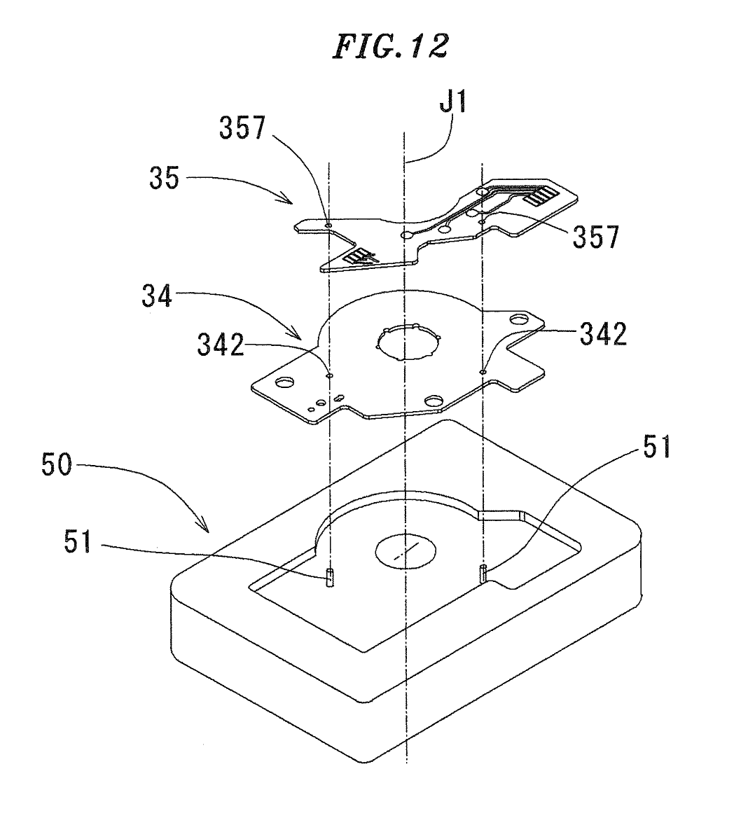

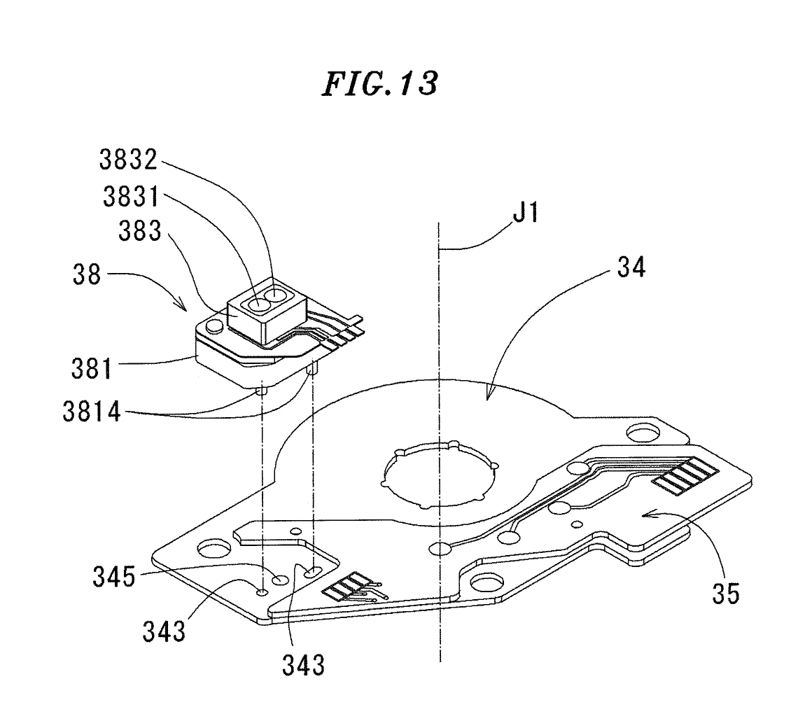

Next, a structure for attaching the position detection unit 38 to the attachment plate 34 and the circuit board 35 will be described with reference to FIGS. 12 to 15. FIG. 12 a schematic exploded perspective view showing an attachment structure of the attachment plate 34 and the circuit board 35. FIGS. 13 to 15 are schematic exploded perspective views showing a structure for attaching the position detection unit 38 to the attachment plate 34 and the circuit board 35 shown in FIG. 12. Although the attachment structure of the position detection unit 38 is shown in FIG. 13, it is the actual practice that the reinforcing plate 3825, the flexible circuit strip 382 and the position detecting element 383 are attached to the supporting base 381 after the supporting base 381 has been attached to the attachment plate 34 in advance. In the present invention, the combination of the attachment plate 34 and the circuit board 35 or the combination of the attachment plate 34, the circuit board 35 and the position detection unit 38 is referred to as a circuit board unit.

Referring to FIG. 12, the attachment plate 34 is placed on an attachment jig 50 having an upper surface on which protrusion portions 51 are formed in the positions corresponding to the first positioning holes 342. The attachment plate 34 is arranged on the upper surface of the attachment jig 50 in a state that the protrusion portions 51 are inserted into the first positioning holes 342. At this time, the protrusion portions 51 protrude axially above the upper surface of the attachment plate 34. Then, the circuit board 35 is fixed to the upper surface of the attachment plate 34 in a state that the attachment plate 34 is attached to the attachment jig 50. The circuit board 35 and the attachment plate 34 are bonded together by means of an adhesive agent.

In this regard, board-side positioning holes 357 are formed in the circuit board 35 in the positions corresponding to the first positioning holes 342 of the attachment plate 34. The circumferential and radial position of the circuit board 35 is decided by inserting the protrusion portions 51 into the board-side positioning holes 357.

Since the protrusion portions 51 of the attachment jig 50 are all used as a reference during the course of attaching the circuit board 35 to the upper surface of the attachment plate 34, it is possible to accurately decide the position of the circuit board 35 relative to the attachment plate 34. In other words, since the radial and circumferential positions of the attachment plate 34 and the circuit board 35 are decided by using the protrusion portions 51 as a common reference, it is possible to attach the circuit board 35 to the attachment plate 34 with a tolerance comparable to the machining accuracy of the protrusion portions 51 of the attachment jig 50.

Referring to FIG. 13, the supporting base 381 is attached to the attachment plate 34. In other words, the lower protrusion portions 3814 of the supporting base 381 are inserted into the second positioning holes 343 of the attachment plate 34. Seeing that one of the second positioning holes 343 is a slot, the supporting base 381 is slightly movable in a state that the lower protrusion portions 3814 of the supporting base 381 are inserted into the second positioning holes 343. This makes it possible to circumferentially adjust the supporting base 381 so that the upper surface of the supporting base 381 can face the center axis J1, namely so that the light-emitting portion 3831 and the light-receiving portion 3832 can be arranged radially from the center axis J1 when the position detecting element 383 is placed on the upper surface of the supporting base 381. Then, the supporting base 381 is radially adjusted to ensure that the light-emitting portion 3831 and the light-receiving portion 3832 lie in a suitable radial position with respect to the pattern formation portion 41 of the disk 40.

Using the second positioning holes (343) of the attachment plate 34, the supporting base 381 is radially and circumferential adjusted with respect to the center axis J1 and is fixed to the attachment plate 34 by means of a screw (not shown). The screw has a generally disk-like screw head that makes contact with a top surface of the recess portion 3811 of the supporting base 381. The through-hole 3812 of the supporting base 381 has a diameter greater than that of a thread portion of the screw but smaller than that of the screw head. This makes it possible to adjust the position of the supporting base 381 relative to the attachment plate 34 without resort to the thread portion of the screw.

Next, the flexible circuit strip 382 to which the reinforcing plate 3825 and the position detecting element 383 are attached in advance is fixed to the upper surface of the supporting base 381. At this time, the upper protrusion portions 3813 formed on the upper surface of the supporting base 381 are arranged in alignment with the positioning holes 3824 of the flexible circuit strip 382. This makes it possible to easily decide the circumferential and radial position of the flexible circuit strip 382 relative to the supporting base 381. Therefore, it is possible to easily and accurately decide the circumferential and radial position of the position detecting element 383 mounted to the flexible circuit strip 382 relative to the center axis J1. The supporting base 381 and the flexible circuit strip 382 are fixed to each other by thermally deforming the upper protrusion portions 3813 of the supporting base 381.

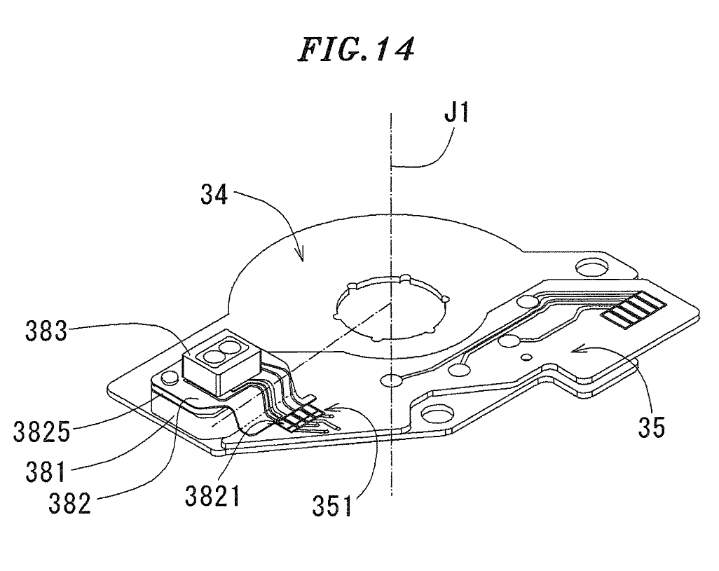

Referring to FIG. 14, the second terminal portion 3821 of the flexible circuit strip 382 is arranged in radial and circumferential alignment with the first terminal portion 351 of the circuit board 35. Owing to the fact that the radial and circumferential positions of the circuit board 35 and the supporting base 381 are decided by using the attachment plate 34 as a common reference, it is possible to set the relative position of the circuit board 35 and the supporting base 381 with increased accuracy.

In particular, since the first positioning holes 342 and the second positioning holes 343 of the attachment plate 34 that serve as a reference of the radial and circumferential positions of the circuit board 35 and the supporting base 381 are formed simultaneously with press-forming the attachment plate 34, it is possible to decide the positions of the circuit board 35 and the supporting base 381 with the accuracy of a press mold. Therefore, it is possible to accurately set the radial and circumferential position of the flexible circuit strip 382 fixed to the upper surface of the supporting base 381 relative to the circuit board 35. As a result, it is possible to easily and accurately align the first terminal portion 351 of the circuit board 35 with the second terminal portion 3821 of the flexible circuit strip 382 in radial and circumferential directions.

In this connection, the flexible circuit strip 382 is adhesively bonded to an upper surface region of the circuit board 35 located between the first terminal portion 351 and a circumferential surface of the circuit board 35 that faces the supporting base 381. This ensures that no force is directly imparted on the second terminal portion 3821 even when the flexible circuit strip 382 is pulled away from the circuit board 35. Therefore, it is possible to prevent the first terminal portion 351 and the second terminal portion 3821 from suffering from bad conduction. In other words, prior to a force being directly applied to the second terminal portion 3821, a resistant force against the external shock is generated in the adhesively bonded region of the flexible circuit strip 382 and the circuit board 35.

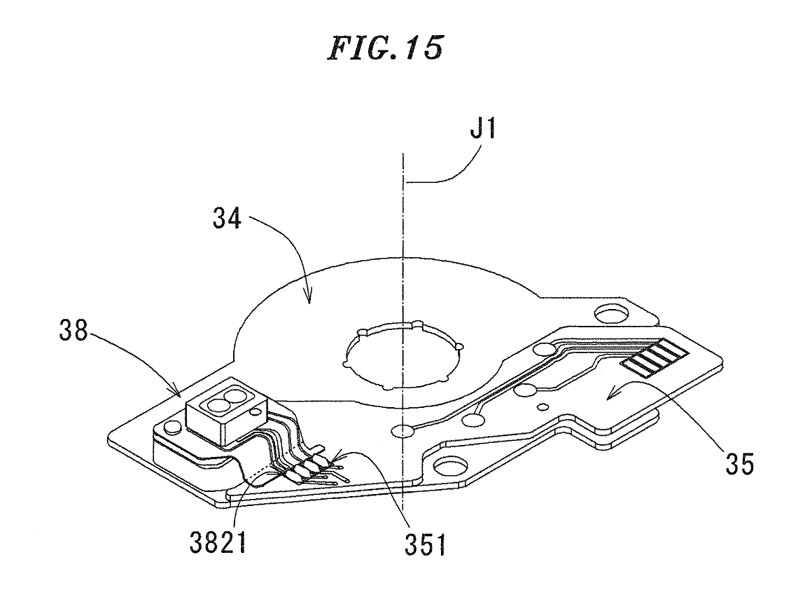

Referring to FIG. 15, the first terminal portion 351 and the second terminal portion 3821 are soldered together. This makes it easy to electrically and mechanically interconnect the first terminal portion 351 and the second terminal portion 3821.

In this regard, since the position detection unit 38 and the circuit board 35 are formed as separate members (that is, the flexible circuit strip 382 of the position detection unit 38 and the circuit board 35 are not formed as a single member), the circuit board 35 can be commonly used for a brushless motor with a position detection unit and that without a position detection unit. This allows two kinds of brushless motors to use the circuit board 35 in common, thereby making it possible to use a single mold in manufacturing the circuit board 35. This helps reduce the cost involved in manufacturing the circuit board 35. Unlike the case where the position detection unit 38 is arranged on the upper surface of the circuit board 35, it is unnecessary for the circuit board 35 to have a space for arranging the position detection unit 38 if the position detection unit 38 is installed outside of the circumferential surface of the circuit board 35 as set forth above. This helps reduce the size of the circuit board 35.

While one embodiment of the present invention has been described hereinabove, the present invention is not limited thereto. Many changes or modifications may be made without departing from the scope of the claims.

For example, although the flexible circuit strip 382 is used to interconnect the circuit board 35 and the first terminal portion 351 in the position detection unit 38 of the present invention, the present invention is not limited thereto. It may be possible to use, e.g., the same material as that of the circuit board 35. In this case, the circuit board 35 may be electrically connected to the first terminal portion 351 by means of, e.g., an “L”-like conductive member.

As another example, although the chucking device 24 of the present invention is configured to have the plurality of chucking claw 243, the present invention is not limited thereto. It may be possible for the chucking device 24 to have only the aligning claws 2411 and to employ a separate mechanism for holding the disk 40 in place.

While the invention has been shown and described with respect to the embodiment, it will be understood by those skilled in the art that various changes and modifications may be made without departing from the scope of the invention as defined in the following claims.

What is claimed is:

1. A circuit board for allowing an electric current to conduct to a position detection unit and a stator having a winding for generating rotating magnetic fields for a brushless motor, the circuit board comprising:
a winding connection portion that connects ends of the winding to the circuit board; and
a first terminal portion adapted to be electrically connected to the position detection unit installed outside of a circumferential surface of the circuit board.

2. A motor driving unit comprising:
the circuit board of claim 1; and
the position detection unit,
wherein the position detection unit includes a position detecting element, a supporting base having an upper surface on which the position detecting element is arranged, and a second terminal portion for electrically connecting the position detecting element to the first terminal portion.

3. The motor driving unit of claim 2, wherein the position detection unit further includes a flexible circuit strip extending between the upper surface of the supporting base and the position detecting element, and
wherein the second terminal portion is provided in the circuit strip.

4. The motor driving unit of claim 3, wherein the circuit strip is fixed to the upper surface of the circuit board at a region between the position detecting element and the second terminal portion.

5. The circuit board of claim 1, wherein the first terminal portion and the second terminal portion are soldered together.

6. The circuit board of claim 1, wherein a uniformly planar attachment plate formed of a thin plate is fixed to a lower surface of the circuit board,
wherein the position detection unit is attached to an upper surface of the attachment plate, and
wherein the positions of the circuit board and the position detection unit are decided by a circuit board positioning portion and a position detection unit positioning portion provided in the attachment plate.

7. The motor driving unit of claim 2, wherein the position detection unit reads information of a label surface of a recording disk.

8. A brushless motor comprising:
the circuit board of claim 1;
a fixed unit having a stator; and
a rotating unit rotatable about a specified center axis, having a rotor magnet arranged in a facing relationship with the stator,
wherein the position detection unit is arranged radially outwardly of the rotating unit.

9. A circuit board unit comprising:
a uniformly planar attachment plate formed of a thin plate; and
a substantially flat circuit board arranged on an upper surface of the attachment plate,
wherein the circuit board allows an electric current to conduct to a position detection unit and a stator having a winding for generating rotating magnetic fields for a brushless motor,
wherein the position detection unit is attached to the upper surface of the attachment plate, and
wherein positions of the circuit board and the position detection unit are decided by a circuit board positioning portion and at least one position detection unit positioning portion provided in the attachment plate.

10. The circuit board unit of claim 9, wherein the attachment plate is formed by press-forming a thin plate, and
wherein each of the circuit board positioning portion and the position detection unit positioning portion is a through-hole and is formed simultaneously with the press-forming.

11. The circuit board unit of claim 10, wherein the position detection unit includes:
a position detecting element; and
a supporting base having an upper surface on which the position detecting element is arranged,
wherein the supporting base is provided with a protrusion portion inserted into the position detection unit positioning portion, and
wherein the position detection unit positioning portion is provided in plural numbers, at least one of which is a slot extending toward a rotational center of the brushless motor.

12. A brushless motor comprising:
the circuit board unit of claim 9;
a fixed unit having a stator; and
a rotating unit rotatable about a specified center axis, having a rotor magnet arranged in a facing relationship with the stator,
wherein the position detection unit is arranged radially outwardly of the rotating unit.
